(19) United States
(12) Patent Application Publication
(10) Pub. No.: US 2024/0258426 A1
(43) Pub. Date: Aug. 1, 2024

(54) SEMICONDUCTOR DEVICE AND METHOD OF MANUFACTURING SAME

(71) Applicant: DB HiTek Co., Ltd., Bucheon-si (KR)

(72) Inventor: Kyoung Hwa JUNG, Icheon-si (KR)

(21) Appl. No.: 18/306,382

(22) Filed: Apr. 25, 2023

(30) Foreign Application Priority Data
Jan. 31, 2023 (KR) 10-2023-0012268

(51) Int. Cl. H01L 29/78; H01L 29/66

(52) U.S. Cl. CPC H01L 29/7816; H01L 29/66681

(57) ABSTRACT

Disclosed is a semiconductor device and a method of manufacturing the same and, more particularly, a semiconductor device and a method of manufacturing the same that improve specific on-resistance (Rsp) characteristics by forming or including a plurality of field oxides between an adjacent gate electrode and a drain to decrease the length of a path for flow of electrons between the drain and the source.

### CROSS REFERENCE TO RELATED APPLICATION

The present application claims priority to Korean Patent Application No. 10-2023-0012268, filed Jan. 31, 2023, the entire contents of which are incorporated herein for all purposes by this reference.

### BACKGROUND OF THE INVENTION

### Field of the Invention

The present disclosure relates to a semiconductor device and a method of manufacturing the same and, more particularly, to a semiconductor device and a method of manufacturing the same that improve specific on-resistance (Rsp) characteristics by forming or including a plurality of field oxides between an adjacent gate electrode and a drain to decrease an electron movement path between the drain and a source.

### Description of the Related Art

A lateral double-diffused metal oxide semiconductor (LDMOS) is a representative power device with fast switching response and high input impedance. Hereinafter, the structure and manufacturing process of a typical LDMOS device will be described in detail.

FIG. 1 is a cross-sectional view of a conventional semiconductor device.

Hereinafter, the structure and problems of a conventional LDMOS semiconductor device will be described in detail with reference to the accompanying drawings.

Referring to FIG. 1, a conventional semiconductor device 9 includes a drift region 910 and a body region 920 at the surface of a substrate 901. In addition, a drain 930 may be in the drift region 910 and a source 940 may be in the body region 920. A gate 950 may be on the substrate 901, between the source 940 and the drain 930. A single field oxide 960 may be between the gate electrode 950 and the drain 930. That is, the single field oxide 960 may be used for both high voltage operation and low voltage operation. The field oxide 960 is formed by local oxidation of silicon (LOCOS). In addition, the field oxide 960 is grown by thermal oxidation, and has a form in which approximately 40% of the thickness thereof is derived from silicon atoms from the substrate 901.

Such a conventional field oxide 960 has a structure extending seamlessly to the drain 930 or to a location adjacent to the drain 930, while overlapping the gate electrode 950. In addition, the conventional field oxide 960 has a thickness of about 2000 to 2200 Å, and the LDMOS semiconductor device 9 has an operating voltage (Vop) of 12 to 70 V, for example. Thus, when the semiconductor device 9 has a relatively low operating voltage (Vop) such as 12 V, for example, the field oxide 960 has a thickness greater than necessary, which causes electrons to move along a non-linear path below the field oxide 960. In other words, since the path along which the electrons move is relatively long, the on-resistance (Rsp) of the device 9 inevitably deteriorates, especially when the device 9 has a low operating voltage (Vop).

To solve the above-mentioned problems, the present inventors have conceived a novel semiconductor device having an improved structure and a method for manufacturing the same, and the details will be described later.

### DOCUMENTS OF RELATED ART

Korean Patent Application Publication No. 10-2012-0055139, entitled “LDMOS SEMICONDUCTOR DEVICE.”

### SUMMARY OF THE INVENTION

The present disclosure has been made to solve the problems of the related art, and an objective of the present disclosure is to provide a semiconductor device and a method of manufacturing the same that reduces or minimizes degradation of on-resistance characteristics of the semiconductor device by connecting two or more field oxides between a gate electrode and a drain to decrease a carrier (electron) path between the drain and the source.

In particular, an objective of the present disclosure is to provide a semiconductor device and a method of manufacturing the same that reduces or minimizes degradation of on-resistance characteristics at relatively low operating voltages.

In addition, an objective of the present disclosure is to provide a semiconductor device and a method of manufacturing the same, having or capable of selectively applying a first structure and a second structure by forming or including a plurality of field oxides in the low voltage region, and forming or including a single field oxide in a high voltage region, so that the density and/or dimensions of the field oxide(s) are different for each operating voltage range in the device.

Furthermore, an objective of the present disclosure is to provide a semiconductor device and a method of manufacturing the same that reduce or prevent process efficiency degradation by forming different field oxides in the first structure and the second structure substantially simultaneously (e.g., in the same processing sequence).

According to one or more embodiments of the present disclosure, there is provided a semiconductor device including a substrate; a drift region on or in the substrate; a body region on or in the substrate; a drain in the drift region; a source in the body region; a gate electrode on the substrate, between the source and the drain ; and a plurality of field oxides between the gate electrode and the drain.

According to another embodiment of the present disclosure, in the semiconductor device of the present disclosure, adjacent ones of the plurality of field oxides may be physically connected to each other.

According to still another embodiment of the present disclosure, in the semiconductor device of the present disclosure, adjacent ones of the plurality of field oxides may overlap each other at edges thereof.

According to still another embodiment of the present disclosure, in the semiconductor device of the present disclosure, the plurality of field oxides may comprise three or more consecutive field oxides.

According to still another embodiment of the present disclosure, in the semiconductor device of the present disclosure, the gate electrode may overlap an adjacent one of the plurality of field oxides.

According to still another embodiment of the present disclosure, the semiconductor device of the present disclosure may further include a body contact contacting the source (e.g., in the body region).

According to still another embodiment of the present disclosure, the semiconductor device of the present disclosure may further include a silicide layer on the source, a body contact, the gate electrode, and the drain.

According to still another embodiment of the present disclosure, in the semiconductor device of the present disclosure, each of the plurality of field oxides may comprise a LOCOS field oxide.

According to still one or more other embodiments of the present disclosure, a semiconductor device of the present disclosure includes a low voltage region; and a high voltage region electrically separated from the low voltage region, wherein the low voltage region may include a substrate; a first drift region on or in the substrate; a first body region on or in the substrate; a first drain in the first drift region; a first source in the first body region; a first gate electrode on the substrate, between the first source and the first drain; and a first structure having a plurality of field oxides between the first gate electrode and the first drain, and the high voltage region may include the substrate; a second drift region on or in the substrate; a second body region on or in the substrate; a second drain in the second drift region; a second source in the second body region; a second gate electrode on the substrate, between the second source and the second drain; and a second structure having a single field oxide between the second gate electrode and the second drain.

According to still another embodiment of the present disclosure, in the semiconductor device of the present disclosure, the second structure (or the single field oxide) may have a greater thickness than the first structure (or each of the plurality of field oxides).

According to still another embodiment of the present disclosure, in the semiconductor device of the present disclosure, in the first structure, each of the plurality of field oxides may comprise a bird's beak, and the bird's beaks of adjacent ones of the plurality of field oxides may overlap each other.

According to still another embodiment of the present disclosure, in the semiconductor device of the present disclosure, the first structure (or each of the plurality of field oxides) may have a thickness of 400 Å or more and 2000 Å or less.

According to one or more embodiments of the present disclosure, there is provided a method of manufacturing a semiconductor device. The method includes forming a drift region on or in a substrate; forming a body region on or in the substrate; forming a plurality of field oxides on or in (e.g., at the surface of) the substrate; forming a gate on the substrate; and forming a source in the body region and a drain in the drift region, wherein the plurality of field oxides may be between the gate and the drain. Alternatively, the plurality of field oxides may be between a pair of adjacent gate electrodes (one of which may be in the gate) and the drain.

According to another embodiment of the present disclosure, in the method of manufacturing a semiconductor device of the present disclosure, the plurality of field oxides may be formed by thermal oxidation.

According to still another embodiment of the present disclosure, in the method of manufacturing a semiconductor device of the present disclosure, the plurality of field oxides may be physically connected.

According to still another embodiment of the present disclosure, the method of manufacturing a semiconductor device of the present disclosure may further include forming a body contact on or in (e.g., at the surface of) the substrate in the body region.

According to still another embodiment of the present disclosure, the method of manufacturing a semiconductor device of the present disclosure may further include forming a silicide layer on the source, a body contact, the gate electrode, and the drain.

According to still another embodiment of the present disclosure, in the method of manufacturing a semiconductor device of the present disclosure, forming the plurality of field oxides may include forming a pad oxide on the substrate; forming a nitride film on the pad oxide; etching the nitride film and the pad oxide; and growing the field oxides (e.g., by thermally oxidizing the exposed substrate).

According to still another embodiment of the present disclosure, in the method of manufacturing a semiconductor device of the present disclosure, etching the nitride film and the pad oxide may include forming a patterned photoresist layer on the nitride film; and removing exposed areas of the nitride film and the pad oxide, wherein the patterned photoresist layer may include a plurality of openings spaced apart from each other.

According to still another embodiment of the present disclosure, a method of manufacturing a semiconductor device of the present disclosure includes forming a drift region and a body region on a surface of a substrate in each of a low voltage region and a high voltage region; forming a first structure comprising a plurality of field oxides connected to each other in the low voltage region; forming a second structure comprising a single field oxide having a greater thickness than the first structure (or the plurality of field oxides) in the high voltage region; forming a gate in each of the low voltage region and the high voltage region; forming a drain in one (or each) of the drift regions and a source in one (or each) of the body regions; and forming a lower insulating film on the substrate, wherein the first structure and the second structure may be formed substantially simultaneously.

The present disclosure has the following effects by the above configurations.

According to the present disclosure, it is possible to reduce or minimize degradation of on-resistance characteristics of a LDMOS semiconductor device by connecting two or more field oxides between a gate electrode and a drain to decrease the length of the carrier path between the drain and the source.

In particular, according to the present disclosure, it is possible to reduce or minimize the degradation of on-resistance characteristics by including a low voltage region in the device, operating at relatively low operating voltages.

In addition, according to the present disclosure, it is possible to selectively apply or to include a first structure and a second structure (e.g., in the LDMOS device) by forming or including a plurality of continuous field oxides in the low voltage region, and forming or including a single field oxide in a high voltage region, so that the density and/or dimensions of the field oxide(s) are different for each operating voltage range in the device.

Furthermore, according to the present disclosure, it is possible to that reduce or prevent process efficiency degradation by forming different field oxides in the first structure and the second structure substantially simultaneously (e.g., in the same processing sequence).

Meanwhile, it should be added that even if effects are not explicitly mentioned herein, the effects described in the following specification expected by the technical features of the present disclosure and their potential effects are treated as if they were described in the present specification.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view of a conventional semiconductor device;

FIG. 2 is a cross-sectional view of a semiconductor device according to one or more embodiments of the present disclosure; and

FIGS. 3 to 13 are cross-sectional views for showing a method of manufacturing a semiconductor device according to embodiments of the present disclosure.

### DETAILED DESCRIPTION OF THE INVENTION

Hereinafter, embodiments of the present disclosure will be described in more detail with reference to the accompanying drawings. The embodiments of the present disclosure may be modified in various forms, and the scope of the present disclosure should not be construed as being limited to the following embodiments, but should be construed based on the matters described in the claims. In addition, these embodiments are provided for reference in order to more completely explain the present disclosure to those of ordinary skill in the art.

Hereinafter, it should be noted that when one component (or layer) is described as being on another component (or layer), the one component (or layer) may be directly on the other component (or layer), or one or more other third components or layers may be between the one component (or layer) and the other component (or layer). In addition, when one component is expressed as being directly on or above another component, no other components are between the components. Moreover, being on “top”, “upper”, “lower”, “above”, “bottom”, “below,” or “one (first) side” or “side” of a component means a relative positional relationship.

The terms first, second, third, etc., may be used to describe various items such as various components, regions and/or parts. However, the items are not limited by these terms.

In addition, it should be noted that, where certain embodiments are otherwise feasible, certain process sequences may be performed other than as described below. For example, two processes described in succession may be performed substantially simultaneously or in the reverse order.

The term “metal oxide semiconductor” (MOS) used below is a general term, and “M” is not limited to only metal, and may refer to various types of conductors. Also, “S” may be a substrate or a semiconductor structure, and “O” is not limited to oxide, and may include various types of organic or inorganic insulating materials.

In addition, the conductivity type or dopant type of a region or component may be defined as “p-type” or “n-type” according to the main carrier characteristics, but this is only for convenience of description, and the technical spirit of the present disclosure is not limited to what is illustrated. For example, hereinafter, “p-type” or “n-type” may be replaced with the more general terms “first conductivity type” or “second conductivity type”, and here, the first conductivity type may refer to p-type, and the second conductivity type may refer to n-type.

Furthermore, it should be understood that “high concentration” and “low concentration” expressing the doping concentration of an impurity region refers to the relative doping concentration of one component to one or more other components.

A semiconductor device 1 below may be, for example, an LDMOS device.

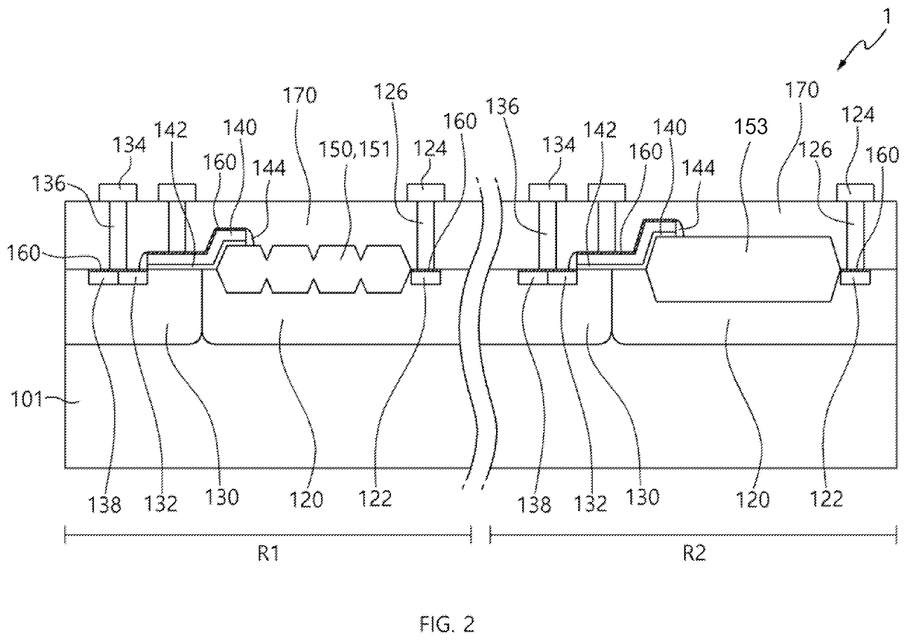

FIG. 2 is a cross-sectional view of a semiconductor device according to one or more embodiments of the present disclosure.

Hereinafter, a semiconductor device 1 according to embodiment(s) of the present disclosure will be described in detail with reference to the accompanying drawings.

Referring to FIG. 2, the present disclosure relates to a semiconductor device 1 and, more particularly, to a semiconductor device 1 that improves specific on-resistance (Rsp) characteristics of the device 1 by forming or including a plurality of field oxides between an adjacent gate electrode and a drain to decrease the length of a path for flow of electrons between the drain and the source.

The semiconductor device 1 includes a substrate 101. A well (not shown) that may at least in part define an active region of the device 1 is on the substrate 101, and the active region may also be defined (at least in part) by a device isolation layer (not shown). The device isolation layer may be formed by, for example, shallow trench isolation (STI). In addition, the substrate 101 may be or comprise a single-crystal silicon substrate doped with a first conductivity type dopant, a P-type diffusion region in the substrate, or a single-crystal silicon substrate with a P-type epitaxial layer epitaxially grown thereon.

A drift region 120 may be in or on the substrate 101. The drift region 120 may contact an adjacent body region 130 or may be apart from the adjacent body region 130 by a predetermined distance, and the scope of the present disclosure is not particularly limited. In addition, the drift region 120 comprises, for example, an impurity doped region having the second conductivity type, and may be below or surround the drain 122 to be described later. A plurality of drift regions 120 may be spaced apart from each other in the substrate 101. Separate drift regions 120 may be in each of the low voltage region R1 and the high voltage region R2. The low voltage region R1 has a relatively low operating voltage (Vop) in the device 1, while the high voltage region R2 has a relatively high operating voltage (Vop). For example, the low voltage region R1 has an operating voltage (Vop) in the range of 9-30 V (e.g., 12 V), and the high voltage region R2 has an operating voltage (Vop) in the range of 30-100 V (e.g., 70 V), but this is only for convenience of description, and the scope of the present disclosure is not limited by the above numerical values.

When the doping concentration in the drift region 120 is below a certain level, the on-resistance characteristics may deteriorate. On the contrary, when the doping concentration is above a second, higher level, the on-resistance characteristics improve, but the breakdown voltage characteristics deteriorate. Thus, it is desirable for the drift region 120 to have an appropriate doping concentration in consideration of these characteristics. It is more preferable that the doping concentration of the drift region 120 is lower than that of the drain 122, which will be described later.

A drain 122 may be in the drift region 120 (e.g., in each of the low voltage region R1 and the high voltage region R2). The drain 122 may be electrically connected to a drain electrode 124 by a drain contact 126, and the drain 122 may be or comprise a high-concentration impurity doped region having the second conductivity type. The drain electrode 124 and the drain contact 126 are electrically connected to the drain 122, and preferably include a conductive metal such as copper, aluminum, tungsten or an alloy thereof, but the scope of the present disclosure is not limited by the above examples. The drain contact 126 may pass through a lower insulating film 170 on the substrate 110. In addition, the lower insulating film 170 may be or comprise a pre-metal dielectric (PMD) layer.

A body region 130 may be in and/or at a surface of the substrate 101 (e.g., in each of the low voltage region R1 and the high voltage region R2). As described above, the body region 130 may contact the adjacent drift region 120 or may be positioned apart from the adjacent drift region 120 by a predetermined distance. The body region 130 may be below or surround a source 132 and a body contact 138 to be described later. In addition, the body region 130 comprises, for example, an impurity doped region having the first conductivity type. The body region 130 preferably has a lower concentration of dopant than the body contact 138, and may be in each of the low voltage region R1 and the high voltage region R2.

A source 132 may be in and/or at the surface of the substrate 101 in the body region 130 (e.g., in each of the low voltage region R1 and the high voltage region R2). The source 132 comprises, for example, a high-concentration impurity doped region having the second conductivity type, and may be electrically or physically connected to a source electrode 134 by a source contact 136. The source electrode 134 and the source contact 136 preferably include a conductive metal such as copper, aluminum, tungsten or an alloy thereof, but the scope of the present disclosure is not limited by the above examples. Like the drain contact 126, the source contact 136 may pass through the lower insulating film 170.

The body contact 138 may be adjacent to or in contact with the source 132 in an individual body region 130. The body contact 138 comprises, for example, a highly-doped region having the first conductivity type, and may be in and/or at the surface of the substrate 101 in the body region 130. The body contact 138 has a higher concentration of dopant than the body region 130, and may provide a path through which excess carriers in the drift region 120 escape from the semiconductor device 1. In addition, the body contact 138 may extend between a pair of adjacent gate electrodes 140 (e.g., between adjacent low voltage regions R1, or between adjacent high voltage regions R2), or a plurality of island type body contacts 138 may be spaced apart from each other. Alternatively, the plurality of body contacts 138 may extend along a separation direction of a pair of adjacent gate electrodes 140 and be spaced apart from each other along a direction orthogonal to the separation direction, and the scope of the present disclosure is not limited by specific examples.

A plurality of gate electrodes 140 are on the substrate 101, separately in the low voltage region R1 and the high voltage region R2. For example, a first gate electrode 140 is in the low voltage region R1, and a second gate electrode 140 is the high voltage region R2. To be specific, the gate electrode 140 may be between the individual drain 122 and the source 132 in an active region of the device 1. The gate electrode 140 is on or over a channel region of the device 1, and the channel region may be turned on or off by a voltage applied to the gate electrode 140. The gate electrode 140 may include conductive polysilicon, a metal, a conductive metal nitride, of a combination thereof, and may be formed by chemical vapor deposition (CVD), physical vapor deposition (PVD), atomic layer deposition (ALD), metalorganic atomic layer deposition (MOALD), metalorganic chemical vapor deposition (MOCVD), or the like.

A gate insulating film 142 is between the gate electrode 140 and the surface of the substrate 101. The gate insulating film 142 may include silicon dioxide, an insulator having a high dielectric constant (e.g., hafnium dioxide, hafnium silicate, zirconium dioxide, zirconium silicate, etc.), or a combination thereof. The gate insulating film 142 may be formed by ALD, CVD, or PVD.

Sidewall surfaces of the gate electrode 140 and the gate insulating film 142 may be covered with a gate spacer 144, and the gate spacer 144 may comprise an oxide (e.g., silicon dioxide), a nitride (e.g., silicon nitride), or a combination thereof.

In the semiconductor device 1 according to embodiments of the present disclosure, a plurality of field oxides 150 may be on or over the channel region and between the gate electrode 140 and the drain 122 in the low voltage region R1. A substantially conventional field oxide 153 may be on or over the channel region and between the gate electrode 140 and the drain 122 in the high voltage region R2. The field oxide 150 is configured to reduce or prevent electric field concentration at the edge or corner of the gate electrode 140, and may be formed, for example, by local oxidation of silicon (LOCOS).

Hereinafter, the structure of a conventional semiconductor device 9 and the problems resulting therefrom, and the semiconductor device 1 according to an embodiment of the present disclosure to solve those problems will be described in detail.

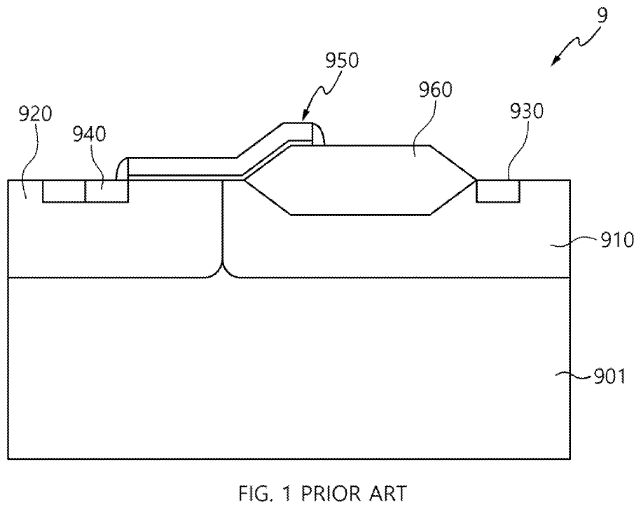

Referring to FIG. 1, the conventional semiconductor device 9 includes a drift region 910 and a body region 920 on the surface of a substrate 901. In addition, a drain 930 may be in the drift region 910 and a source 940 may be in the body region 920. A gate 950 may be on the substrate 901, between the source 940 and the drain 930. A single field oxide 960 may be between the gate electrode 950 and the drain 930. That is, the single field oxide 960 may be used for both high voltage operation and low voltage operation. The field oxide 960 is formed by local oxidation of silicon (LOCOS). In addition, the field oxide 960 is grown by thermal oxidation, and has a form in which approximately 40% of the thickness thereof is derived from silicon atoms from the substrate 901.

Such a conventional field oxide 960 has a structure extending seamlessly to the drain 930 or to a location adjacent to the drain 930, while overlapping the gate electrode 950. In addition, the conventional field oxide 960 has a thickness of about 2000 to 2200 Å, and the LDMOS semiconductor device 9 having an operating voltage (Vop) of 12 to 70 V, for example. Thus, when the semiconductor device 9 has a relatively low operating voltage (Vop) such as 12 V, for example, the field oxide 960 has a thickness greater than necessary, which causes electrons to move along a non-linear path below the field oxide 960. In other words, since the path along which the electrons move is relatively long, the on-resistance (Rsp) of the device 9 inevitably deteriorates, especially when the device 9 has a low operating voltage (Vop).

Referring to FIG. 2, in order to compensate for the above-described issues, the semiconductor device 1 according to embodiments of the present disclosure includes a plurality of field oxides 150 between the gate electrode 140 and the drain 122 in the low voltage region of the device 1. Hereinafter, a structure including a plurality of continuous and/or connected field oxides is referred to as a “first structure 151”, whereas a structure including only a single field oxide between the gate electrode 140 and the drain 122 is referred to as a “second structure 153”.

In the first structure 151, the plurality of field oxides 150 are in a defined space between the gate electrode 140 and the drain 122, instead of one field oxide as in the related art. The first structure 151 preferably contains two or more field oxides 150, and more preferably three or more field oxides 150. The first structure 151 may be in the low voltage region R1.

In the first structure 151, it is preferable that adjacent field oxides 150 are physically connected to each other. For example, edge portions (e.g., bird's beaks) of adjacent field oxides 150 in the first structure 155 may overlap each other. In other words, it is desirable that the bird's beaks of adjacent field oxides 150 overlap with or extend into each other.

As such, when a plurality of field oxides 150 are connected and/or formed within a limited area, the thicknesses of the individual field oxides 150 may be less than that of the second structure 153 having a single field oxide. For example, the thickness of the individual field oxides 150 of the first structure 151 may be in the range of about 400 Å to 2000 Å, and the individual field oxide 150 of the first structure 151 may have a thickness less than that of the field oxide 150 of the second structure 153. For example, the thickness of the second, single field oxide 153 may be in the range of 2000 Å to about 2200 Å.

In addition, at least one of the plurality of field oxides 150 in the first structure 151 may have a different width from the rest of the field oxide(s), or may have the substantially same width as the rest of the field oxide(s), and the scope of the present disclosure is not limited by specific examples.

Due to the first structure 151, the carrier path in the low voltage region R1 may be relatively short, thereby minimizing the on-resistance (Rsp) deterioration resulting from the formation of the field oxides 150.

Since the second structure 153 in the high voltage region R2 may have substantially the same shape as the conventional field oxide 960, a detailed description thereof will be omitted.

In the semiconductor device 1 according to the present disclosure, the first structure 151 and the second structure 153 may be in a single semiconductor device 1, and thus, it is possible to prevent the on-resistance (Rsp) from deteriorating more than necessary, while improving the breakdown voltage (BV) of the semiconductor device 1.

The gate electrode 140 preferably overlaps the adjacent field oxide 150 in the low voltage region R1 and the adjacent field oxide or 153 in the high voltage region R2.

In addition, a metal silicide film 160 may be on the drain 122, the source 132, the gate electrode 140, and the body contact 136. In general, in a MOSPET device, the silicide film 160 may comprise a self-aligned silicide (salicide) of a metal such as cobalt (Co), nickel (Ni), tungsten (W) or titanium (Ti), to improve contact resistance and thermal stability.

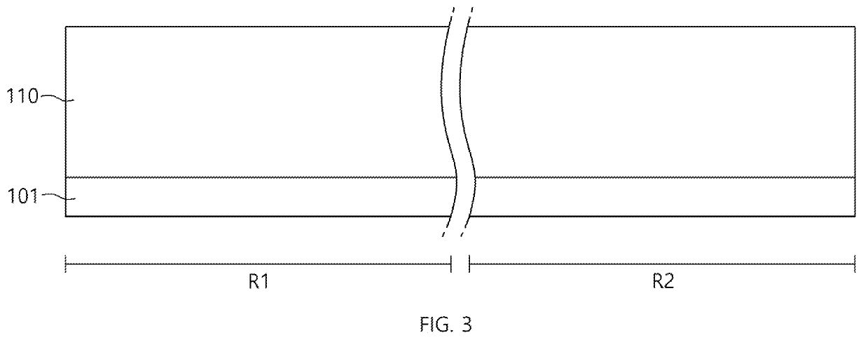

FIGS. 3 to 13 are cross-sectional views for showing a method of manufacturing a semiconductor device according to embodiments of the present disclosure.

Hereinafter, the method of manufacturing the semiconductor device according to embodiments of the present disclosure will be described in detail with reference to the accompanying drawings.

First, referring to FIG. 3, an epitaxial layer 110 having a first conductivity type is grown on a substrate 101. Hereinafter, the substrate 101 may include all epitaxial layers thereon. The epitaxial layer 110 may comprise, for example, a silicon layer having an identical or substantially identical crystal lattice as the substrate 101, and may further include an impurity having the first conductivity type.

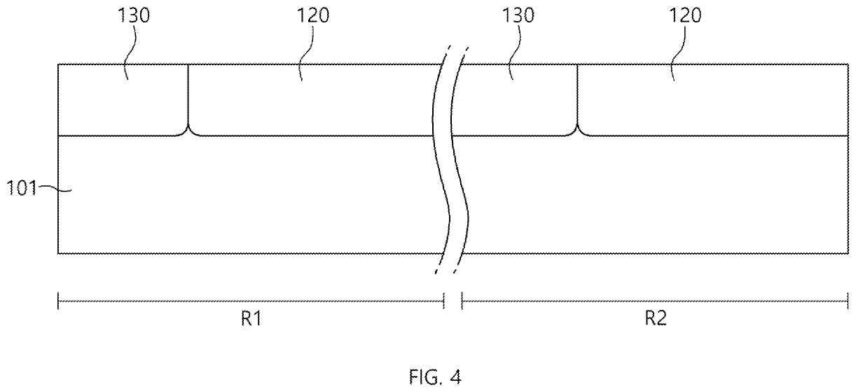

Thereafter, referring to FIG. 4, a drift region 120 and a body region 130 may be formed in the substrate 101. For example, the drift region 120 may be or comprise an impurity doped region having the second conductivity type, and the body region 130 may be or comprise an impurity doped region having the first conductivity type. The drift region 130 and the body region 130 may be formed by ion implantation process using different corresponding mask patterns (not shown). The drift region 130 and the body region 130 are formed in both the low voltage region R1 and the high voltage region R2. That is, a first drift region 130 and a first body region 130 are formed in the low voltage region R1, and a second drift region 130 and a second body region 130 are formed in the high voltage region R2.

Thereafter, an active region may be defined by forming a device isolation layer (not shown). As previously mentioned, the device isolation layer may be formed by, for example, shallow trench isolation (STI). A plurality of field oxides 150/153 may also be formed. The field oxides 150/153 may be formed by local oxidation of silicon (LOCOS). Hereinafter, the process of forming the field oxides 150/153 will be described in detail.

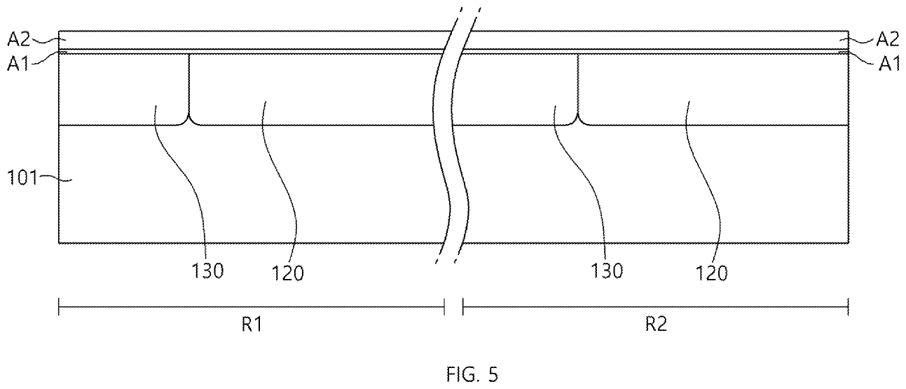

Referring to FIG. 5, a pad oxide A1 (e.g., comprising silicon dioxide) is formed on the substrate 101 by blanket deposition (e.g., CVD or PVD) or thermal oxidation, and a nitride film A2 (e.g., comprising silicon nitride, Si₃N₄) is formed on the pad oxide A1 by blanket deposition (e.g., CVD or PVD). The pad oxide A1 serves as an intermediate layer or buffer, since the difference in coefficients of thermal expansion between the nitride film A2 and the substrate 101 is large.

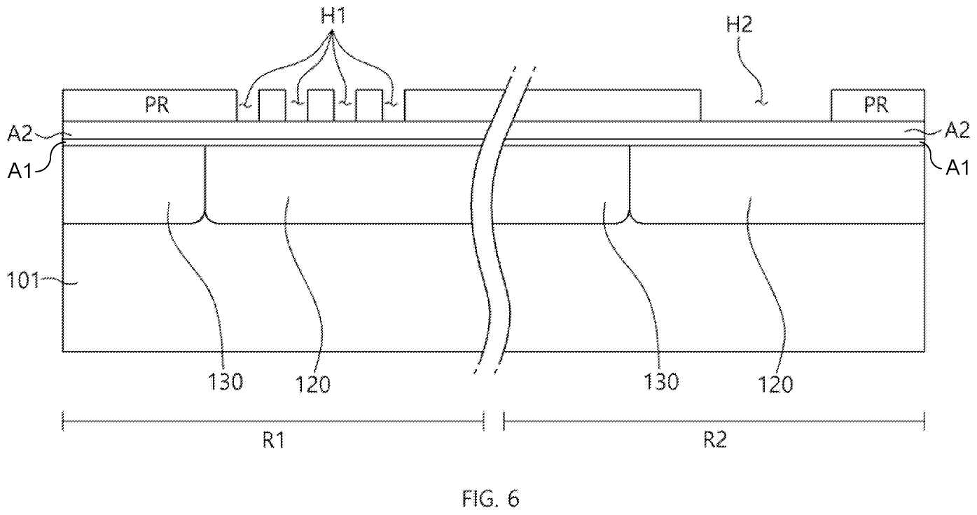

Thereafter, referring to FIG. 6, a patterned photoresist layer PR is formed on the nitride film A2 by conventional photolithography and development, with a plurality of openings H1 and H2 in the pattern. Using the patterned photoresist layer PR as a mask, the nitride film A2, the pad oxide A1, and optionally, the surface of the substrate 101 may be sequentially etched. The low voltage region R1 includes a plurality of openings H1 in the patterned photoresist layer PR, and the openings H1 may be spaced apart from each other. A single opening H2 may be in the patterned photoresist layer PR in the high voltage region R1.

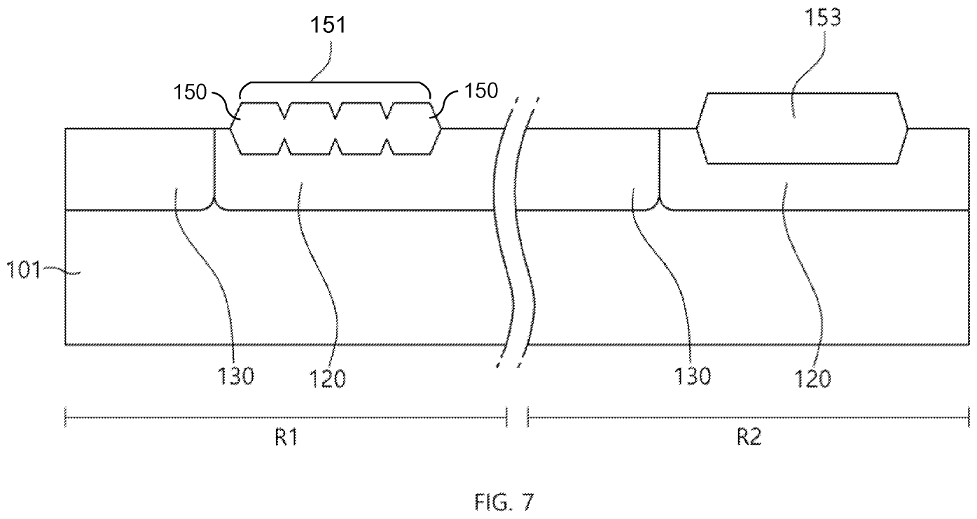

Thereafter, referring to FIG. 7, the field oxides are grown by thermal oxidation using the etched nitride layer A2 as a mask. Accordingly, the first structure 151 includes a plurality of field oxides 150 that may be physically connected to each other, while the second structure 153 includes a single field oxide 150, and a detailed description thereof will be omitted. As previously described, in the first structure 151, edges or peripheral regions (e.g., bird's beaks) of adjacent field oxides 150 may overlap each other. Then, the nitride film A2 is removed (e.g., by wet etching using buffered or unbuffered phosphoric acid), and the pad oxide A1 remaining on the substrate 101 may be removed in a subsequent process (e.g., by wet etching using a buffered hydrofluoric acid).

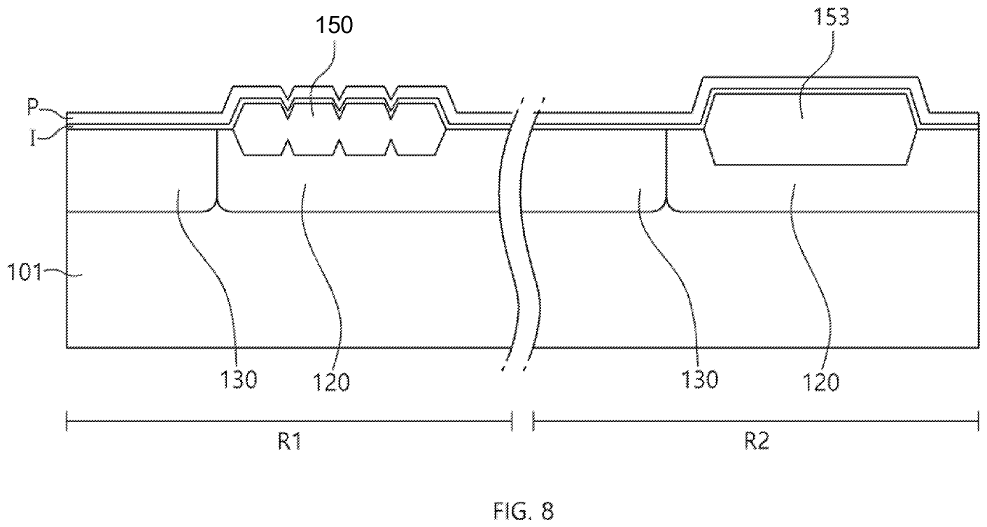

Thereafter, a gate including a gate insulating film 142, a gate electrode 140, and a gate spacer 144 may be formed on the substrate 101, which will be described in detail. Referring to FIG. 8, for example, an insulating film I and, on the insulating film I, a gate film P including a conductive polysilicon film are sequentially blanket- and/or conformally deposited (e.g., by CVD or PVD). However, the gate film P may further include a metal, a conductive metal nitride, or a combination thereof, in addition to the conductive polysilicon. The insulating film I may include silicon dioxide, an insulator having a high dielectric constant, or a combination thereof.

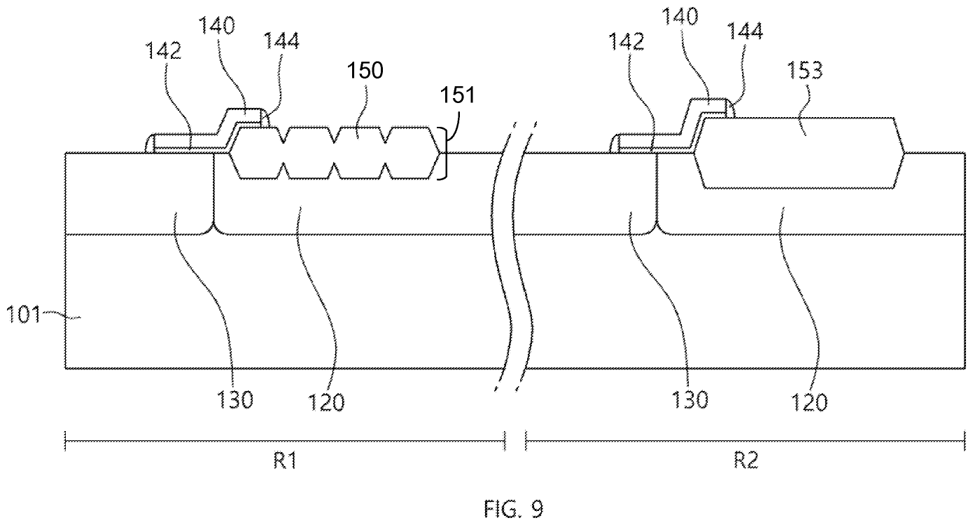

Thereafter, referring to FIG. 9, after forming a mask pattern (not shown), the gate film P and the insulating film I are sequentially etched to form the gate electrodes 140 and the gate insulating films 142 having sidewalls.

Then, one or more additional insulating films are deposited on the gate electrode 140 and the substrate 101 by, for example, conformal deposition such as CVD (chemical vapor deposition), and the additional insulating films are anisotropically dry etched to form gate spacers 144 on each of the gate electrodes 140.

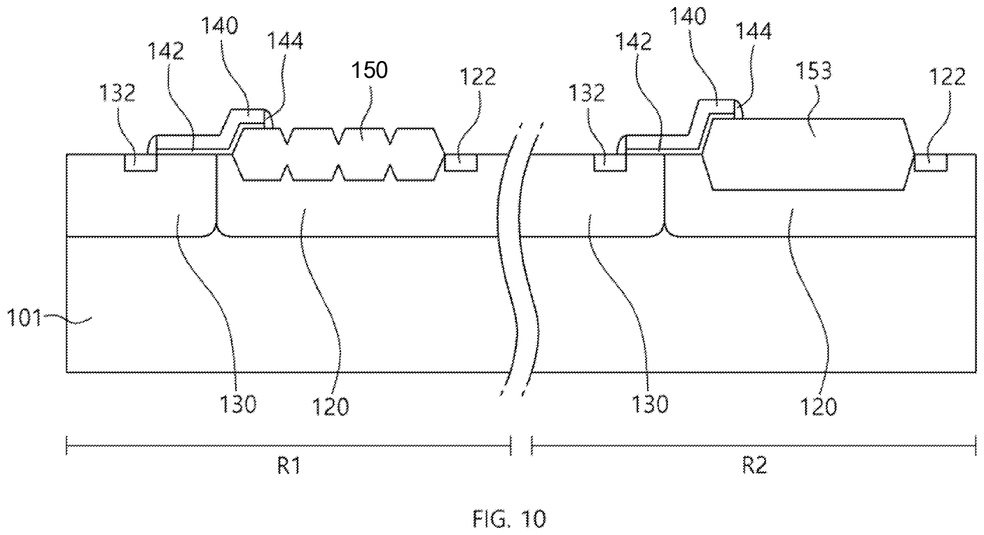

Thereafter, referring to FIG. 10, a drain 122 and a source 132, each of which contain a high concentration of dopant impurities, may be formed by ion implantation through a patterned mask. The device isolation layers (not shown) and/or the field oxide 153 may form part of the mask for the drain 122, and the gate electrodes 140 may form part of the mask for the source 132.

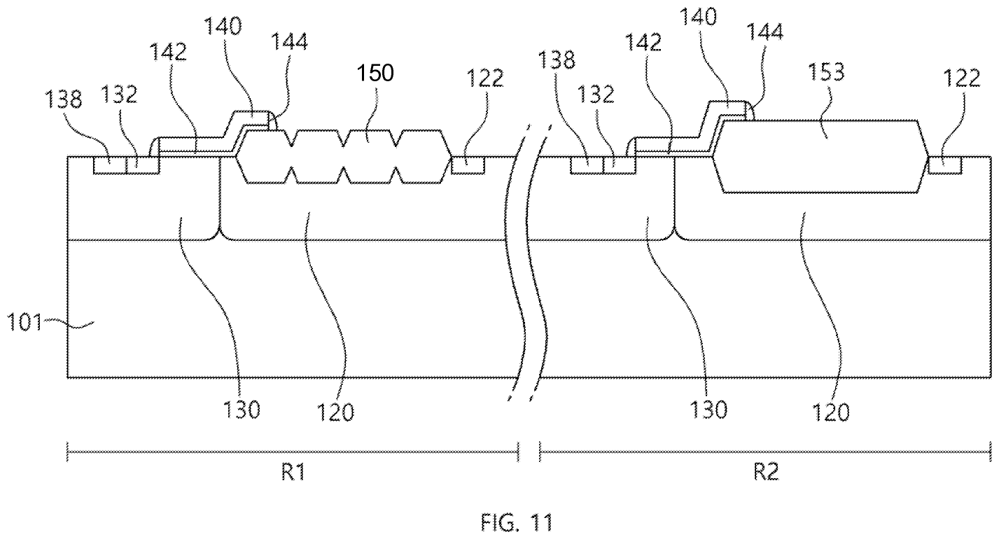

Thereafter, referring to FIG. 11, a body contact 138 may be formed in the substrate 101 and/or in the body region 130 (e.g., at the uppermost surface thereof). The body contact 138 may be formed by ion implantation process using a mask pattern (not shown).

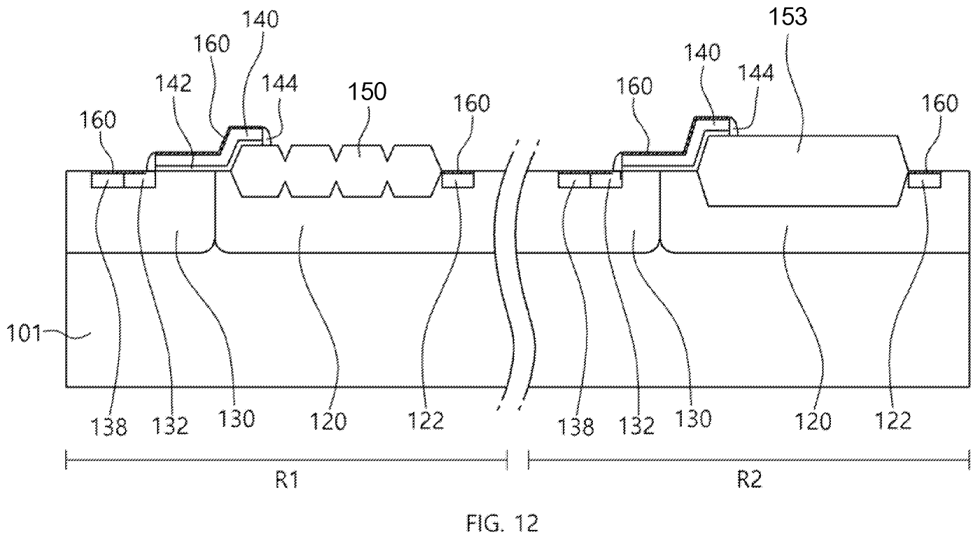

Thereafter, referring to FIG. 12, a self-aligned silicide (salicide) film 160 may be formed on or over the drain 122, the source 132, the body contact 136, the gate electrodes 140, and/or (optionally) the substrate 101 by first depositing a metal layer such as cobalt (Co), nickel (Ni), tungsten (W) or titanium (Ti), then annealing to form the corresponding metal silicide. The salicide film 160 is configured to improve contact resistance and thermal stability (e.g., of the ohmic contact or interface between an overlying contact to be formed later and the underlying drain 122, source 132, body contact 136, or gate electrode 140).

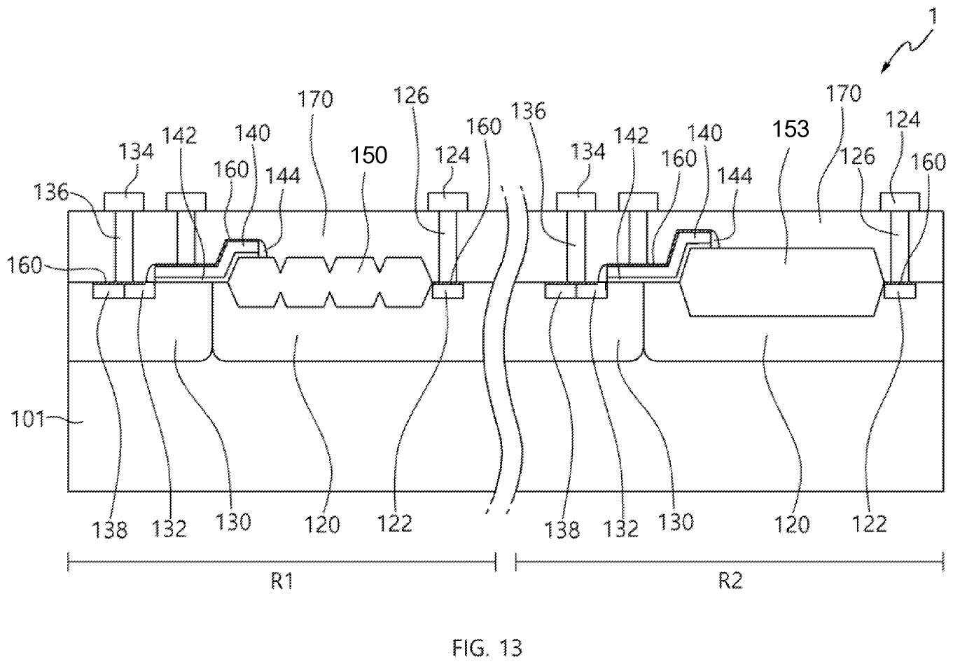

Finally, referring to FIG. 13, after forming a lower insulating film 170 on the substrate 101 (e.g., by conventional blanket deposition and polishing [e.g., chemical mechanical polishing, or CMP]), a drain contact 126 and a source contact 136 are formed by conventionally patterning a photoresist to form a mask having a plurality of openings therein, etching the exposed areas of the lower insulating film 170 to form contact holes, and depositing one or more liner layers and/or metals in the contact holes and on the lower insulating film 170, then removing the excess liner layer(s) and/or metals from the uppermost surface of the lower insulating film 170 (e.g., by CMP), source contacts 136, drain contacts 126, and gate contacts (not labeled in FIG. 13) are formed. A drain electrode 124, a gate electrode (not labeled in FIG. 13), and a source electrode 134 are conventionally formed on the lower insulating film 170, and a detailed description thereof will be omitted.

The above detailed description is illustrative of the present disclosure. In addition, the above description shows and describes various embodiments of the present disclosure, and the present disclosure can be used in various other combinations, modifications, and environments. In other words, changes or modifications are possible within the scope of the concept of the disclosure disclosed herein, the scope equivalent to the written disclosure, and/or within the scope of skill or knowledge in the art. The above-described embodiments describe various states for implementing the technical idea(s) of the present disclosure, and various changes for specific applications and/or fields of use of the present disclosure are possible. Accordingly, the detailed description is not intended to limit the present disclosure to the disclosed embodiments.

What is claimed is:

1. A semiconductor device, comprising:
a substrate;
a drift region on or in the substrate;
a body region on or in the substrate;
a drain in the drift region;
a source in the body region;
a gate electrode on the substrate, between the source and the drain; and
a plurality of field oxides between the gate electrode and the drain.

2. The semiconductor device of claim 1, wherein adjacent ones of the plurality of field oxides are physically connected to each other.

3. The semiconductor device of claim 1, wherein adjacent ones of the plurality of field oxides overlap each other at edges thereof.

4. The semiconductor device of claim 1, wherein the plurality of field oxides comprise three or more consecutive field oxides.

5. The semiconductor device of claim 1, wherein the gate electrode overlaps an adjacent one of the plurality of field oxides.

6. The semiconductor device of claim 5, further comprising:
a body contact contacting the source.

7. The semiconductor device of claim 6, further comprising:
a silicide layer on the source, the body contact, the gate electrode, and the drain.

8. The semiconductor device of claim 5, wherein each of the plurality of field oxides comprise a LOCOS field oxide.

9. A semiconductor device, comprising:
a low voltage region; and
a high voltage region electrically separated from the low voltage region,
wherein the low voltage region comprises:
a substrate;
a first drift region on or in the substrate;
a first body region on or in the substrate;
a first drain in the first drift region;
a first source in the first body region;
a first gate electrode on the substrate, between the first source and the first drain; and
a first structure having a plurality of field oxides between the first gate electrode and the first drain, and
the high voltage region comprises:
the substrate;
a second drift region on or in the substrate;
a second body region on or in the substrate;
a second drain in the second drift region;
a second source in the second body region;
a second gate electrode on the substrate, between the second source and the second drain; and
a second structure having a single field oxide between the second gate electrode and the second drain.

10. The semiconductor device of claim 9, wherein the second structure has a greater thickness than the first structure.

11. The semiconductor device of claim 9, wherein in the first structure, each of the plurality of field oxides may comprise a bird's beak, and the bird's beaks of adjacent ones of the plurality of field oxides overlap each other.

12. The semiconductor device of claim 9, wherein the first structure has a thickness of 400 Å or more and 2000 Å or less.

13. A method of manufacturing a semiconductor device, the method comprising:
forming a drift region on a substrate;
forming a body region on or in the substrate;
forming a plurality of field oxides on the substrate;
forming a gate on the substrate; and
forming a source in the body region, and a drain in the drift region,
wherein the plurality of field oxides are between the gate and the drain.

14. The method of manufacturing a semiconductor device of claim 13, wherein the plurality of field oxides are formed by thermal oxidation.

15. The method of manufacturing a semiconductor device of claim 13, wherein the plurality of field oxides are physically connected.

16. The method of manufacturing a semiconductor device of claim 13, further comprising:
forming a body contact on or in the substrate in the body region.

17. The method of manufacturing a semiconductor device of claim 13, further comprising:
forming a silicide layer on the source, a body contact, the gate, and the drain.

18. The method of manufacturing a semiconductor device of claim 13, wherein forming the plurality of field oxides comprises:
forming a pad oxide on the substrate;
forming a nitride film on the pad oxide;
etching the nitride film and the pad oxide; and
growing the plurality of field oxides.

19. The method of manufacturing a semiconductor device of claim 18, wherein etching the nitride film and the pad oxide comprises:
forming a patterned photoresist layer on the nitride film; and
removing exposed areas of the nitride film and the pad oxide,
wherein the patterned photoresist layer comprises a plurality of openings spaced apart from each other.

20. A method of manufacturing a semiconductor device, the method comprising:
forming a drift region and a body region on or in a substrate in each of a low voltage region and a high voltage region;
forming a first structure comprising a plurality of field oxides connected to each other in the low voltage region;
forming a second structure comprising a single field oxide having a greater thickness than the first structure in the high voltage region;
forming a gate in each of the low voltage region and the high voltage region;
forming a drain in one or each of the drift regions and a source in one or each of the body regions; and
forming a lower insulating film on the substrate,
wherein the first structure and the second structure are formed substantially simultaneously.
